(19) United States
(12) Patent Application Publication
(10) Pub. No.: US 2026/0333900 A1
(43) Pub. Date: Oct. 22, 2026

(54) IMAGE SENSOR DEVICE AND METHOD OF MANUFACTURING THE SAME

(71) Applicant: Taiwan Semiconductor Manufacturing Company, Ltd., Hsinchu (TW)

(72) Inventors: Chi-Hsien Chung, New Taipei City (TW); Tzu-Jui Wang, Fengshan City (TW); Chia-Chi Hsiao, Tianzhong Township (TW); Chun-Hao Chuang, Hsinchu City (TW); Chen-Jong Wang, Hsin-Chu (TW); Dun-Nian Yaung, Taipei City (TW)

(21) Appl. No.: 19/721,053

(22) Filed: Jun. 26, 2026

Related U.S. Application Data
(62) Division of application No. 18/321,281, filed on May 22, 2023.
(60) Provisional application No. 63/481,416, filed on Jan. 25, 2023.

(51) Int. Cl. H10F 39/00; H10F 39/12; H10F 39/18

(52) U.S. Cl. CPC H10F 39/8023; H10F 39/014; H10F 39/024; H10F 39/182; H10F 39/199; H10F 39/8037; H10F 39/8053; H10F 39/8063; H10F 39/807; H10F 39/811

(57) ABSTRACT

An integrated chip including a first semiconductor substrate. The first semiconductor substrate includes a doped region. A first photodetector and a second photodetector are in the first semiconductor substrate. A trench isolation layer at least partially surrounds the first photodetector and the second photodetector and extends between the first photodetector and the second photodetector. The trench isolation layer has a first pair of sidewalls. The first semiconductor substrate extends from the first photodetector, between the first pair of sidewalls, to the second photodetector. The doped region is between the first pair of sidewalls. The first photodetector and a first gate partially form a first transistor. The second photodetector and a second gate partially form a second transistor. A second semiconductor substrate is over the first gate and the second gate. A third transistor is along the second semiconductor substrate. The third transistor is coupled to the first transistor.

### REFERENCE TO RELATED APPLICATIONS

This Application is a Divisional of U.S. Application number 18/321,281, filed on May. 22, 2023, which claims the benefit of U.S. Provisional Application number 63/481,416, filed on Jan. 25, 2023. The contents of the above-referenced Patent Applications are hereby incorporated by reference in their entirety.

### BACKGROUND

Complementary metal-oxide semiconductor (CMOS) image sensors are used in a wide range of modern-day electronic devices, such as, for example, cameras, tablets, smart phones, and so on. CMOS image sensors may be front-side illuminated (FSI) or back-side illuminated (BSI). Compared to FSI image sensors, BSI image sensors have better sensitivity, better angular response, and greater metal routing flexibility.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a top view of some embodiments of an integrated chip comprising a pixel along a first semiconductor substrate.

FIGS. 2 and 3 illustrate cross-sectional views of some embodiments of the integrated chip of FIG. 1.

FIG. 4 illustrates a circuit diagram of some embodiments of the integrated chip of FIGS. 1-3.

FIG. 5 illustrates a top view of some embodiments of the integrated chip of FIG. 1 in which a plurality of pixels are arranged along the first semiconductor substrate.

FIG. 6 illustrates a cross-sectional view of some embodiments of the integrated chip of FIG. 5.

FIG. 7 illustrates a top view of some embodiments of the integrated chip of FIG. 1 in which four transfer transistors share a floating diffusion region.

FIGS. 8 and 9 illustrate cross-sectional views of some embodiments of the integrated chip of FIG. 7.

FIG. 10 illustrates a circuit diagram of some embodiments of the integrated chip of FIGS. 7-9.

FIG. 11 illustrates a top view of some other embodiments of an integrated chip comprising a pixel along a first semiconductor substrate.

FIG. 12 illustrates a cross-sectional view of some embodiments of the integrated chip of FIG. 11.

FIGS. 13-36 illustrate various views of some embodiments of a method for forming an integrated chip comprising a pixel along a first semiconductor substrate.

FIG. 37 illustrates a flow diagram of some embodiments of a method for forming an integrated chip comprising a pixel along a first semiconductor substrate.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

An integrated chip includes an image sensor. The image sensor includes a pixel along a semiconductor substrate. The pixel includes a first photodetector and a first floating diffusion region in the substrate. The pixel further includes a second photodetector and a second floating diffusion region in the substrate. A first transfer gate is over the first photodetector and a second transfer gate is over the second photodetector. The first photodetector, the first floating diffusion region, and the first transfer gate partially form a first transfer transistor. The second photodetector, the second floating diffusion region, and the second transfer gate partially form a second transfer transistor. The pixel further includes pixel transistors (e.g., a reset transistor, a source-follower transistors, and a select transistor) along the substrate and beside the transfer transistors. For example, source/drain regions of the pixel transistors are in the substrate and beside the photodetectors. The pixel transistors are coupled to one or more of the transfer transistors.

Because the pixel transistors are in the substrate and beside the transfer transistors, a performance of the integrated chip may be reduced. For example, the source/drain regions of the pixel transistors take up space in the substrate, thereby reducing an available space for the first and second photodetectors. Consequently, a photosensitive area of the pixel may be reduced. Further, because the pixel transistors are arranged along the substrate, reducing the pitch of the pixel may be challenging.

In various embodiments of the present disclosure, the pixel transistors are spaced over the substrate to increase the space available for the photodetectors in the substrate. For example, the photodetectors are disposed in a first substrate, the transfer transistors are arranged along the first substrate, and the pixel transistors are arranged along a second substrate. The second substrate is bonded over the first substrate.

By disposing the pixel transistors along a separate substrate than the transfer transistors and the photodetectors, a performance of the integrated chip can be improved. For example, because the pixel transistors are arranged along the second substrate, separate from the first substrate, an area of the photodetectors can be increased. Thus, the photosensitive area of the pixel can be increased. Further, because less transistors are arranged along the first substrate, the pitch of the pixel can be more easily reduced.

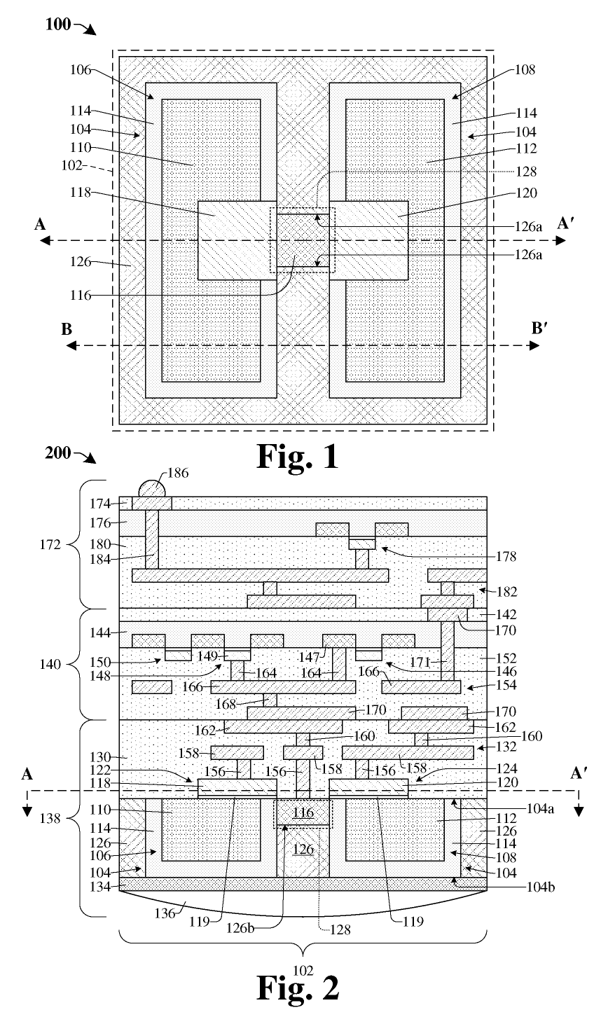

FIG. 1 illustrates a top view 100 of some embodiments of an integrated chip comprising a pixel 102 along a first semiconductor substrate 104. FIG. 2 illustrates a first cross-sectional view 200 of some embodiments of the integrated chip of FIG. 1. FIG. 3 illustrates a second cross-sectional view 300 of some embodiments of the integrated chip of FIG. 1 and FIG. 2. In some embodiments, cross-sectional view 200 of FIG. 2 may, for example, be taken across line A-A′ of FIG. 1. In some embodiments, cross-sectional view 300 of FIG. 3 may, for example, be taken across line B-B′ of FIG. 1.

Referring to FIGS. 1-3, the integrated chip includes a first chip 138. The first chip 138 includes the pixel 102. The pixel 102 includes a first photodetector 106 and a second photodetector 108 in the first substrate 104. For example, the first substrate 104 includes a first photodiode region 110, a second photodiode region 112, and a bulk region 114. The first photodiode region 110 and the second photodiode region 112 are arranged along a frontside 104a of the first substrate 104. The bulk region 114 of the first substrate 104 surrounds the first and second photodiode regions 110, 112. The bulk region 114 of the first substrate 104 has a first doping type (e.g., p-type). The first and second photodiode regions 110, 112 have a second doping type (e.g., n-type), different than the first doping type. The first photodetector 106 is formed by a first p-n junction between the first photodiode region 110 and the bulk region 114 of the first substrate 104. The second photodetector 108 is formed by a second p-n junction between the second photodiode region 112 and the bulk region 114 of the first substrate 104.

The pixel 102 may be referred to as a dual photodetector pixel because the pixel 102 includes the first and second photodetectors 106, 108 in the same pixel. In some instances, dual photodetectors pixels have improved performance (e.g., focusing speed) compared to single photodetector pixels.

A first transfer gate 118 and a second transfer gate 120 are over the first photodetector 106 and the second photodetector 108, respectively. A gate dielectric layer 119 is between the first and second transfer gates 118, 120 and the first substrate 104. The first transfer gate 118, the gate dielectric layer 119, and the first photodetector 106 partially form a first transfer transistor 122. The second transfer gate 120, the gate dielectric layer 119, and the second photodetector 108 partially form a second transfer transistor 124.

The first chip 138 further includes a first dielectric structure 130 over the first substrate 104. A first metal interconnect structure 132 is disposed within the first dielectric structure 130 and coupled to various features of the pixel 102 (e.g., the floating diffusion region 116, the transfer gates 118, 120, and/or some other features). The first metal interconnect structure 132 includes metal contacts 156, metal lines 158, metal vias 160, and metal pads 162. A color filter 134 and a micro-lens 136 (through which photons may impinge on the photodetectors 106, 108) are arranged along a backside 104b of the first substrate 104.

A second chip 140 is over the first chip 138. The second chip 140 includes a second semiconductor substrate 144. Pixel transistors are arranged along the second substrate 144. For example, a first pixel transistor 146 (e.g., a reset transistor), a second pixel transistor 148 (e.g., a source-follower transistor), and a third pixel transistor 150 (e.g., a select transistor) are arranged along the second substrate 144. Because the pixel transistors 146, 148, 150 are arranged along a different substrate than the photodetectors 106, 108, there is more space available in the first substrate 104 for the photodetectors 106, 108. As a result, a photosensitive area of the pixel 102 can be increased.

A second dielectric structure 152 is under the second substrate 144 (e.g., along a frontside of the second substrate 144) and a second metal interconnect structure 154 is within the second dielectric structure 152. The second metal interconnect structure 154 includes metal contacts 164, metal lines 166, metal vias 168, and metal pads 170. A first backside dielectric layer 142 is over the second substrate 144 (e.g., along a backside of the second substrate 144). The first chip 138 and the second chip 140 are bonded together along the dielectric structures 130, 152 and the metal interconnect structures 132, 154. For example, in some embodiments, the dielectric structures 130, 152 and the metal interconnect structures 132, 154 include bonding interface layers (e.g., bonding layers 2102, 3202 of FIG. 35) along which the first and second chips 138, 140 are bonded.

In some embodiments, metal contact(s) 156, metal line(s) 158, metal via(s) 160, and metal pad(s) 162 of the first metal interconnect structure 132 are over and coupled to the transfer gates 118, 120 for controlling the voltage at the transfer gates 118, 120. For example, a first set of metal interconnects of the first metal interconnect structure 132 are coupled to the first transfer gate 118 and a second set of metal interconnects of the first metal interconnect structure 132, separate and isolated from the first set, are coupled to the second transfer gate 120 so the transfer transistors 122, 124 can be individually controlled to separately access the first and second photodetectors 106, 108. The transfer gates 118, 120 are coupled to the second chip 140 through the first and second metal interconnect structures 132, 154.

A trench isolation layer 126 laterally surrounds the first photodetector 106 and the second photodetector 108 in a closed path along a boundary of the pixel 102. In addition, the trench isolation layer 126 extends directly between the first photodetector 106 and the second photodetector 108. Because the trench isolation layer 126 surrounds the first photodetector 106 and the second photodetector 108 along the boundary of the pixel 102, the trench isolation layer 126 can isolate the pixel 102 from neighboring pixels (not shown), thereby reducing a cross-talk between the pixel 102 and the neighboring pixels. Further, because the trench isolation layer 126 extends directly between the first photodetector 106 and the second photodetector 108, cross-talk between the first and second photodetectors can be reduced. Furthermore, isolating the pixels using the trench isolation layer 126 may improve a full well capacity (FWC) of the pixels.

The trench isolation layer 126 has an opening 128 therein. The opening 128 is delimited by a pair of sidewalls 126a of the trench isolation layer 126. In some embodiments, the opening 128 is further delimited by an upper surface 126b of the trench isolation layer 126. The opening 128 (e.g., the sidewalls 126a that delimit the opening 128) is directly between the first photodetector 106 and the second photodetector 108. The first substrate 104 extends continuously from the first photodetector 106, between the pair of sidewalls 126a and over the upper surface 126b of the trench isolation layer 126, to the second photodetector 108.

The first substrate 104 further includes a floating diffusion region 116. The floating diffusion region 116 is laterally spaced between the first photodetector 106 and the second photodetector 108. The floating diffusion region 116 has the second doping type (e.g., n-type). The floating diffusion region 116 is arranged in the opening 128. For example, the floating diffusion region 116 is directly between the pair of sidewalls 126a and directly over the upper surface 126b of the trench isolation layer 126.

Because the trench isolation layer 126 has the opening 128 therein, the floating diffusion region 116 can be disposed in the first substrate 104 directly between the first and second photodetectors 106, 108. Thus, the floating diffusion region 116 can be shared between the first and second transfer transistors 122, 124. For example, the first transfer gate 118, the gate dielectric layer 119, the first photodetector 106, and the floating diffusion region 116 form the first transfer transistor 122 while the second transfer gate 120, the gate dielectric layer 119, the second photodetector 108, and the floating diffusion region 116 form the second transfer transistor 124. Because the transfer transistors 122, 124 share the floating diffusion region 116, a performance of the integrated chip can be improved. For example, by sharing a single floating diffusion region between the transfer transistors 122, 124 (instead of the transfer transistors 122, 124 having individual floating diffusion regions), the number of individual floating diffusion regions in the first substrate 104 can be reduced. As a result, a floating diffusion capacitance of the image sensor may be reduced and a conversion gain of the image sensor may be improved.

In some embodiments, the first photodiode region 110 and the floating diffusion region 116 form source/drain regions of the first transfer transistor 122. Similarly, the second photodiode region 112 and the floating diffusion region 116 form source/drain regions of the second transfer transistor 124. Source/drain region(s) may refer to a source or a drain, individually or collectively dependent upon the context. In some embodiments, the bulk region 114 of the first substrate 104 forms channel regions of the transfer transistors 122, 124.

Metal interconnects of the first and second metal interconnect structures 132, 154 couple a source/drain region 147 of the first pixel transistor 146, a gate 149 of the second pixel transistor 148, and the floating diffusion region 116. For example, metal contact(s) 156, metal line(s) 158, metal via(s) 160, and metal pad(s) 162 of the first metal interconnect structure 132 and metal contact(s) 164, metal line(s) 166, metal via(s) 168, and metal pad(s) 170 of the second interconnect structure 154 couple the floating diffusion region 116 to the source/drain region 147 of the first pixel transistor 146 and to the gate 149 of the second pixel transistor 148. The second pixel transistor 148 is coupled to the third pixel transistor 150.

In some embodiments, a third chip 172 is over the second chip 140. The third chip 172 includes a third semiconductor substrate 176. The third chip 172 may be or comprise an application-specific integrated chip (ASIC) or the like. In some embodiments, the third chip comprises circuitry such as, for example, a transistor 178 along the third substrate 176. A third dielectric structure 180 is under the third substrate 176 (e.g., along a frontside of the third substrate 176) and a third metal interconnect structure 182 is within the third dielectric structure 180.

The second chip 140 and the third chip 172 are bonded together along the third dielectric structure 180, the first backside dielectric layer 142, and the second and third metal interconnect structures 154, 182. In some embodiments, the second metal interconnect structure 154 includes a metal through-substrate via (TSV) 171 extending through the second substrate 144 and the first backside dielectric layer 142 to couple the second metal interconnect structure 154 to the third metal interconnect structure 182.

In some embodiments, the third chip 172 includes a second backside dielectric layer 174 over the third substrate 176 (e.g., along a backside of the third substrate 176). In some embodiments, the third metal interconnect structure 182 includes a TSV 184 extending through the third substrate 176 and a metal bump 186 over the second backside dielectric layer 174 and coupled to the TSV 184.

In some embodiments, the substrates 104, 144, 176 may, for example, comprise silicon or some other suitable semiconductor. In some embodiments, the trench isolation layer 126 may, for example, comprise silicon dioxide, some other suitable dielectric, tungsten, or some other suitable metal. In some embodiments, the gate dielectric layer 119 may, for example, comprise silicon dioxide, some high-k dielectric, or some other suitable material. In some embodiments, the transfer gates 118, 120 may, for example, comprise polysilicon, metal, or some other suitable material. In some embodiments, the dielectric layers of the dielectric structures 130, 152, 180 and the backside dielectric layers 142, 174 may, for example, comprise silicon dioxide, silicon nitride, or some other suitable materials. In some embodiments, the metal interconnects of the metal interconnect structures 132, 154, 182 may, for example, comprise tungsten, copper, aluminum, or some other suitable material.

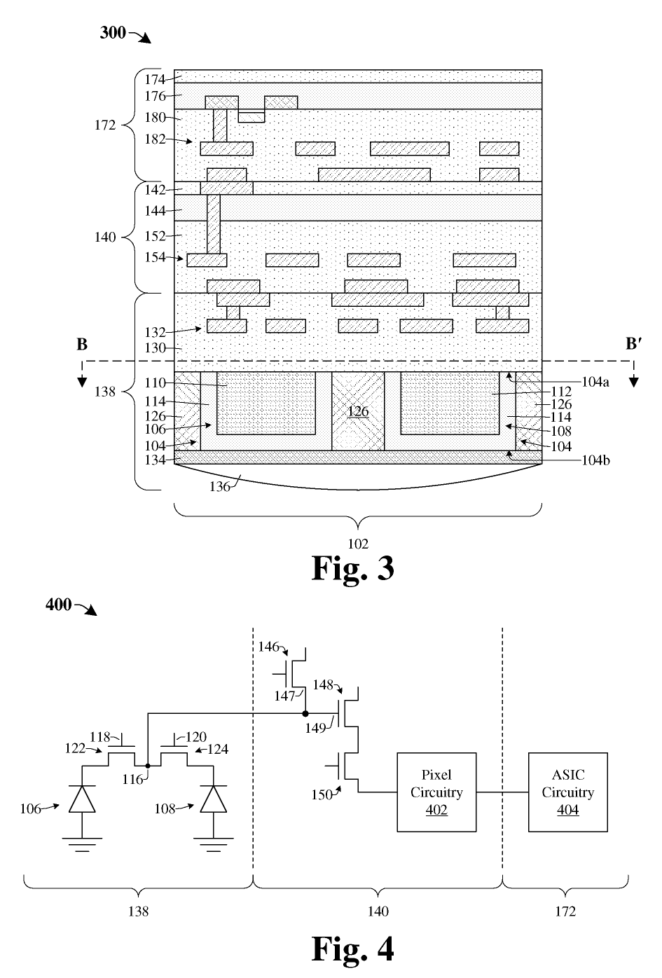

FIG. 4 illustrates a circuit diagram 400 of some embodiments of the integrated chip of FIGS. 1-3.

The first chip 138 includes the first and second transfer transistors 122, 124. The second chip 140 includes the pixel transistors 146, 148, 150. The first transfer transistor 122 and the second transfer transistor 124 share the floating diffusion region 116. The first photodetector 106 and the second photodetector 108 are selectively coupled to the floating diffusion region 116 by the first transfer transistor 122 and the second transfer transistor 124, respectively. The floating diffusion region 116 is coupled to the source/drain region 147 of the first pixel transistor 146 and the gate 149 of the second pixel transistor 148. The second pixel transistor 148 and the third pixel transistor 150 are serially coupled. In some embodiments, the second chip 140 further includes pixel circuitry 402 coupled to the third pixel transistor 150. The pixel circuitry 402 may, for example, comprise additional transistors, diodes, resistors, capacitors, inductors, or some other suitable circuitry. In some embodiments, the pixel circuitry 402 is coupled to ASIC circuitry 404 of the third chip 172. The ASIC circuitry 404 may, for example, comprise transistors (e.g., transistor 178 of FIG. 2), diodes, resistors, capacitors, inductors, or some other suitable circuitry.

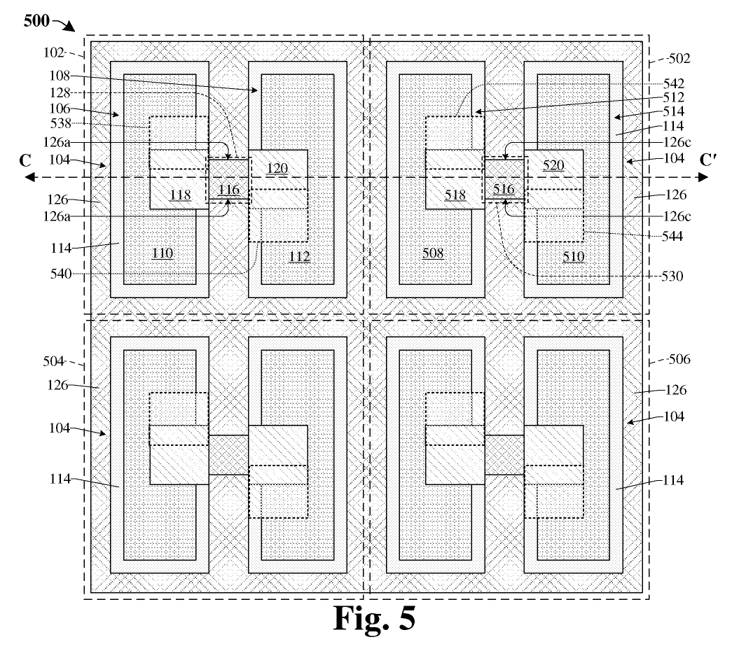

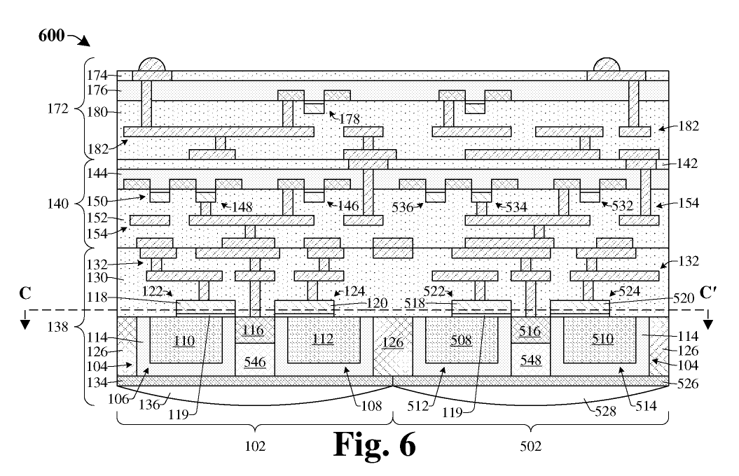

FIG. 5 illustrates a top view 500 of some embodiments of the integrated chip of FIG. 1 in which a plurality of pixels are arranged along the first substrate 104. FIG. 6 illustrates a cross-sectional view 600 of some embodiments of the integrated chip of FIG. 5. In some embodiments, cross-sectional view 600 of FIG. 6 may, for example, be taken across line C-C′ of FIG. 5.

Referring to FIGS. 5 and 6, a first pixel 102, a second pixel 502, a third pixel 504, and a fourth pixel 506 are arranged along the first substrate 104. In some embodiments, each of the pixels 102, 502, 504, 506 include a pair of photodetector regions forming a pair of photodetectors, a floating diffusion region, a pair of transfer gates forming a pair of transfer transistors that share the floating diffusion region, a color filter, and a micro-lens. For example, the first pixel 102 includes the first and second photodiode regions 110, 112 forming the first and second photodetectors 106, 108, the first floating diffusion region 116, the first and second transfer gates 118, 120 forming the first and second transfer transistors 122, 124, the first color filter 134, and the first micro-lens 136. Similarly, the second pixel 502 includes third and fourth photodiode regions 508, 510 forming third and fourth photodetectors 512, 514, a second floating diffusion region 516, third and fourth transfer gates 518, 520 forming third and fourth transfer transistors 522, 524, a second color filter 526, and a second micro-lens 528.

In some embodiments, the transfer gates (e.g., the first and second transfer gates 118, 120) are symmetric about the floating diffusion regions (e.g., the first floating diffusion region 116). In some other embodiments, the transfer gates are asymmetric about the floating diffusing regions (e.g., as shown by dashed features 538, 540, 542, 544 representing shifted transfer gates).

The trench isolation layer 126 surrounds, and extends between, each of the pixels 102, 502, 504, 506. The trench isolation layer 126 electrically and/or optically isolates the pixels from each other, thereby reducing cross-talk between the pixels. The trench isolation layer 126 has openings therein between each of the pairs of photodetectors. For example, a first pair of sidewalls 126a of the trench isolation layer 126 delimit a first opening 128 in the trench isolation layer 126 and a second pair of sidewalls 126c delimit a second opening 530 in the trench isolation layer 126. In some embodiments (e.g., as illustrated in FIG. 2), the trench isolation layer 126 extends directly under the first and second openings 128, 530 so the first and second openings 128, 530 are further delimited by upper surfaces (e.g., upper surface 126b of FIG. 2) of the trench isolation layer 126. In some other embodiments (e.g., as shown in FIG. 6), the first substrate 104 further comprises first and second implant regions 546, 548 in the first and second openings 128, 530, respectively (e.g., directly between the pairs of sidewalls 126a, 126c of the trench isolation layer 126 that delimit the first and second openings 128, 530, respectively). The implant regions have the first doping type (e.g., p-type). The implant regions provide electrical isolation between the photodetectors. For example, the first implant region 546 provides isolation between the first photodetector 106 and the second photodetector 108. The second implant region 548 provides isolation between the third photodetector 512 and the fourth photodetector 514.

The floating diffusion regions are arranged in the openings. For example, the first and second floating diffusion regions 116, 516 are between the sidewalls of the trench isolation layer 126 that delimit the first and second openings 128, 530, respectively. In some embodiments, the floating diffusion regions 116, 516 are over the upper surfaces (e.g., upper surface 126b of FIG. 2) of the trench isolation layer 126. In some other embodiments, the floating diffusion regions are over the implant regions (e.g., the first and second implant regions 546, 548).

In some embodiments, pixel transistors are disposed over, and coupled to, each of the transfer transistors. For example, in some embodiments, the first pixel transistor 146, the second pixel transistor 148, and the third pixel transistor 150 are over and coupled to the first floating diffusion region 116. Similarly, a fourth pixel transistor 532, a fifth pixel transistor 534, and a sixth pixel transistor 536 are over and coupled to the second floating diffusion region 516.

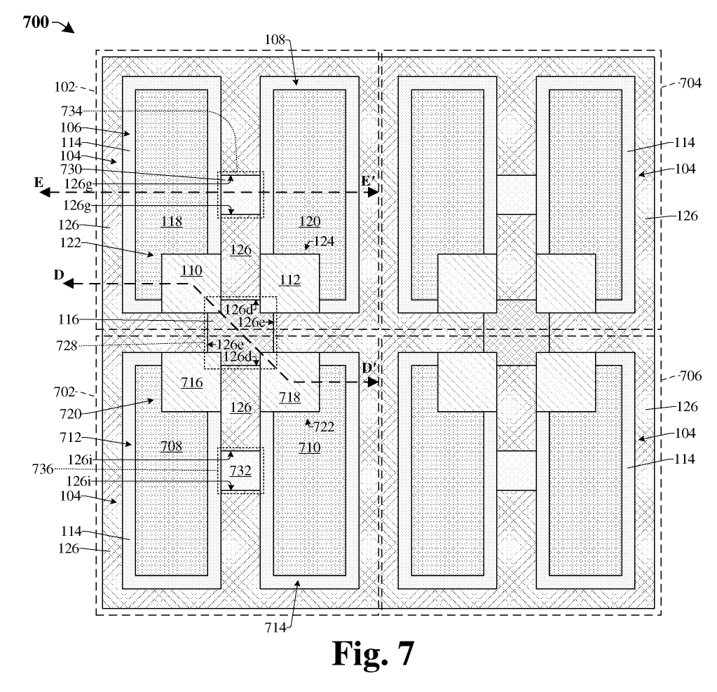

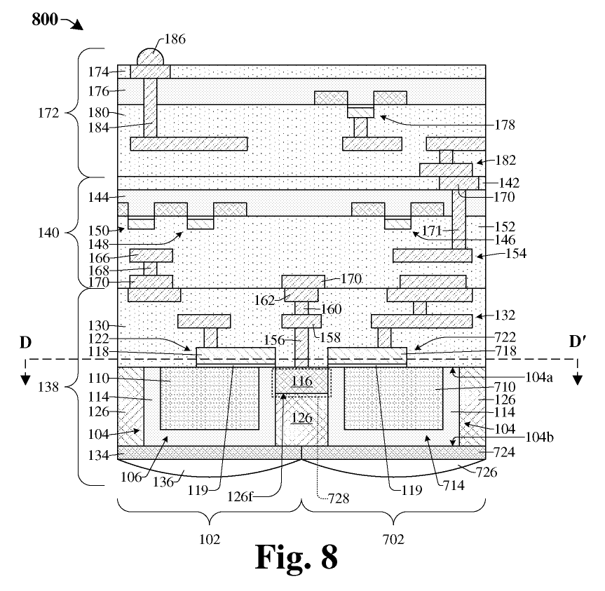

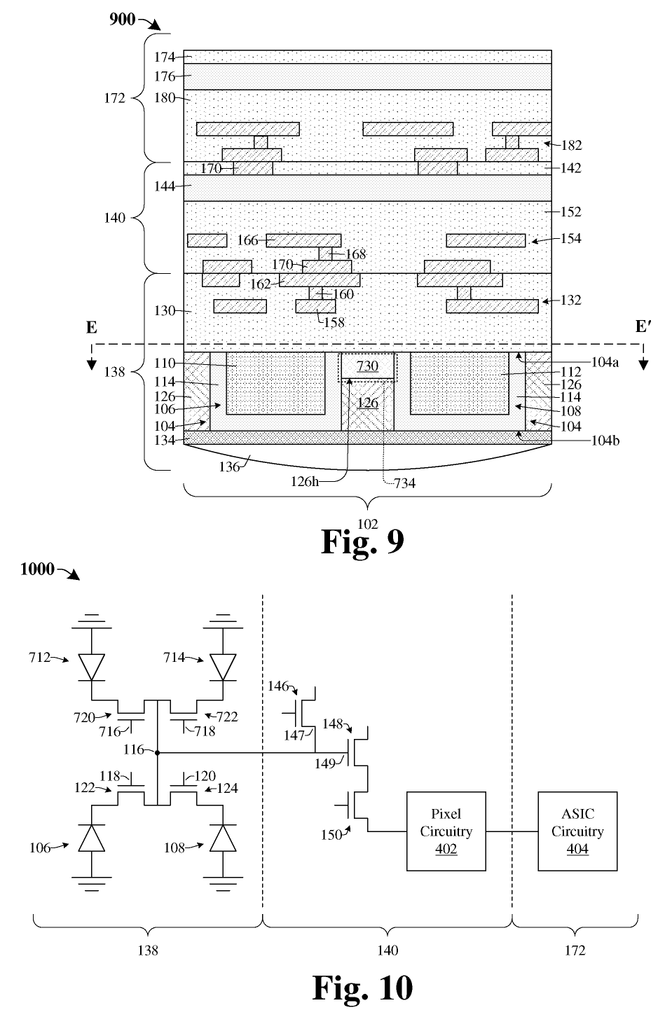

FIG. 7 illustrates a top view 700 of some embodiments of the integrated chip of FIG. 1 in which four transfer transistors share a floating diffusion region. FIG. 8 illustrates a first cross-sectional view 800 of some embodiments of the integrated chip of FIG. 7. FIG. 9 illustrates a second cross-sectional view 900 of some embodiments of the integrated chip of FIG. 8. FIG. 10 illustrates a circuit diagram 1000 of some embodiments of the integrated chip of FIGS. 7-9. In some embodiments, cross-sectional view 800 of FIG. 8 may, for example, be taken across line D-D′ of FIG. 7. In some embodiments, cross-sectional view 900 of FIG. 9 may, for example, be taken across line E-E′ of FIG. 7.

Referring to FIGS. 7-10, the integrated chip includes a first pixel 102, a second pixel 702, a third pixel 704, and a fourth pixel 706 arranged along the first substrate 104. The first pixel 102 includes the first and second photodiode regions 110, 112 forming the first and second photodetectors 106, 108, the first and second transfer gates 118, 120 forming the first and second transfer transistors 122, 124, the first color filter 134, and the first micro-lens 136. Similarly, the second pixel 702 includes third and fourth photodiode regions 708, 710 forming third and fourth photodetectors 712, 714, third and fourth transfer gates 716, 718 forming third and fourth transfer transistors 720, 722, a second color filter 724, and a second micro-lens 726.

A first opening 728 is in the trench isolation layer 126 between the first pixel 102 and the second pixel 502. The first opening 728 is formed by a first pair of sidewalls 126d and a second pair of sidewalls 126e of the trench isolation layer 126. In some embodiments, the first opening 728 is further delimited by a first upper surface 126f of the trench isolation layer 126. The first substrate 104 extends continuously through the first opening 728 (e.g., between the first pair of sidewalls 126d, between the second pair of sidewalls 126e, and over the first upper surface 126f of the trench isolation layer 126) between each of the photodetectors 106, 108, 712, 714 of the first and second pixels 102, 702. The floating diffusion region 116 is disposed in the first opening 728 (e.g., between the first pair of sidewalls 126d, between the second pair of sidewalls 126e, and over the first upper surface 126f of the trench isolation layer 126).

The floating diffusion region 116 is shared by the first pixel 102 and the second pixel 702. For example, the first transfer transistor 122, the second transfer transistor 124, the third transfer transistor 720, and the fourth transfer transistor 722 share the floating diffusion region 116. By sharing a single floating diffusion region 116 between the four transfer transistors, the number of individual floating diffusion regions in the first substrate 104 can be further reduced. As a result, a floating diffusion capacitance of the image sensor may be further reduced and a conversion gain of the image sensor may be further improved. The first pixel transistor 146, the second pixel transistor 148, and the third pixel transistor 150 are over and coupled to the first floating diffusion region 116.

In some embodiments, a second opening 734 is in the trench isolation layer 126 between the first photodetector and the second photodetector 108. The second opening 734 is delimited by a third pair of sidewalls 126g of the trench isolation layer 126. In some embodiments, the second opening 734 is further delimited by a second upper surface 126h of the trench isolation layer 126. The first substrate 104 extends continuously through the second opening 734 (e.g., between the third pair of sidewalls 126g and over the second upper surface 126h of the trench isolation layer 126) between the first and second photodetectors 106, 108. Similarly, a third opening 736 is in the trench isolation layer 126 between the third photodetector 712 and the fourth photodetector 714. The third opening 736 is delimited by a fourth pair of sidewalls 126i of the trench isolation layer 126. In some embodiments, the third opening 736 is further delimited by a third upper surface (not shown) of the trench isolation layer 126. The first substrate 104 extends continuously through the third opening 736 (e.g., between the fourth pair of sidewalls 126i and over the third upper surface (not shown) of the trench isolation layer 126) between the third and fourth photodetectors 712, 714.

In some embodiments, the first substrate 104 includes a first implant region 730 in the second opening 734 and a second implant region 732 in the third opening 736. The first implant region 730 and the second implant region 732 have the first doping type (e.g., p-type). In some embodiments, the implant regions provide isolation between the neighboring photodetectors (e.g., 106, 108 and 712, 714). In some other embodiments, the implant regions (e.g., 730, 732) are body contact regions for coupling to the bulk region 114 of the first substrate 104.

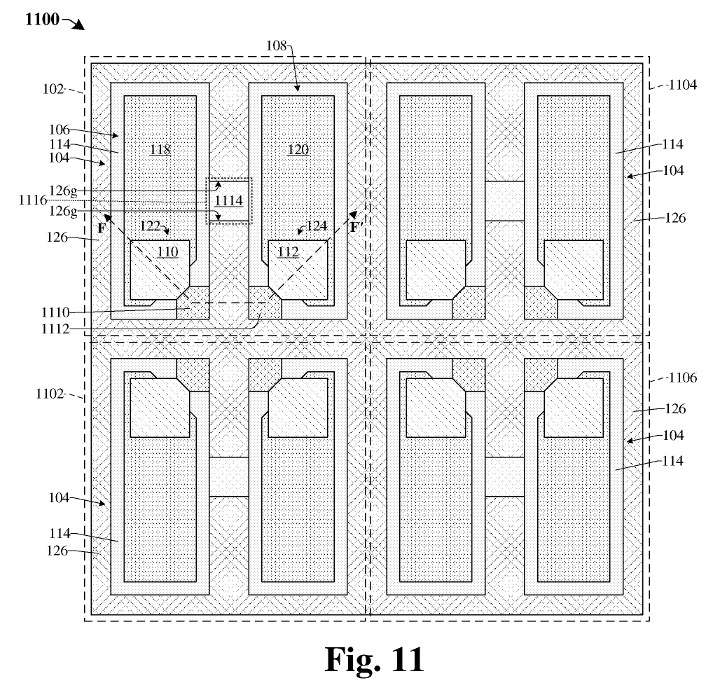

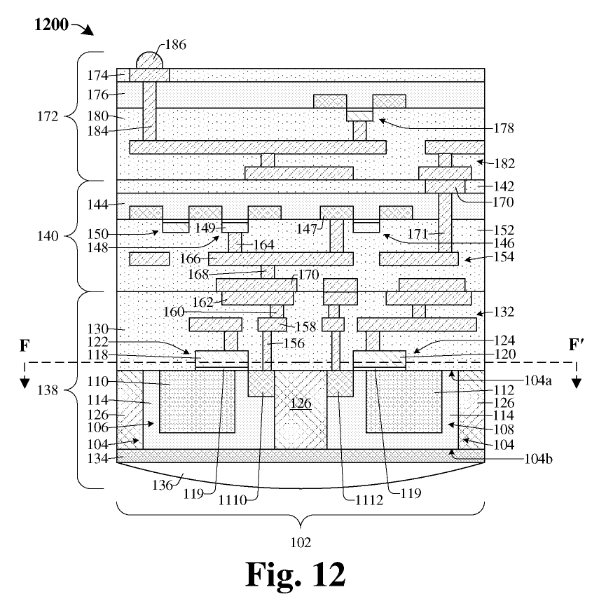

FIG. 11 illustrates a top view 1100 of some other embodiments of an integrated chip comprising a pixel 102 along a first substrate 104. FIG. 12 illustrates a cross-sectional view 1200 of some embodiments of the integrated chip of FIG. 11. In some embodiments, cross-sectional view 1200 of FIG. 12 may, for example, be taken across line F-F′ of FIG. 11.

The integrated chip includes a first pixel 102, a second pixel 1102, a third pixel 1104, and a fourth pixel 1106 arranged along the first substrate 104. Each pixel includes a pair of floating diffusion regions. For example, the first pixel 102 includes first and second floating diffusion regions 1110, 1112. The first photodetector 106, the first floating diffusion region 1110, and the first transfer gate 118 form the first transfer transistor 122. The second photodetector 108, the second floating diffusion region 1112, and the second transfer gate 120 form the second transfer transistors 122, 124

The trench isolation layer 126 has openings therein between each of the pairs of photodetectors. For example, a first opening 1116 in the trench isolation layer 126 is delimited by a first pair of sidewalls 126g of the trench isolation layer 126. The first substrate 104 comprises implant regions in the openings. For example, a first implant region 1114 is in the first opening 1116. The implant regions have the first doping type (e.g., p-type). In some embodiments, the implant regions isolate the photodetectors from each other. In some other embodiments, the first implant region 1114 is a body contact region. Because the pixels share a single implant region, a performance of the pixels may be improved.

In some embodiments, a first set of pixel transistors (e.g., the first pixel transistor 146, the second pixel transistor 148, and the third pixel transistor 150) are over and coupled to the first floating diffusion region 1110, a second set of pixel transistors (not shown) are over and coupled to the second floating diffusion region 1112.

FIGS. 13-36 illustrate views 1300-3600 of some embodiments of a method for forming an integrated chip comprising a pixel along a first semiconductor substrate. Although FIGS. 13-36 are described in relation to a method, it will be appreciated that the structures disclosed in FIGS. 13-36 are not limited to such a method, but instead may stand alone as structures independent of the method.

FIGS. 13-30 illustrate views 1300-3000 of some embodiments of a method for forming a first chip 138 including a pixel 102 along a first substrate 104.

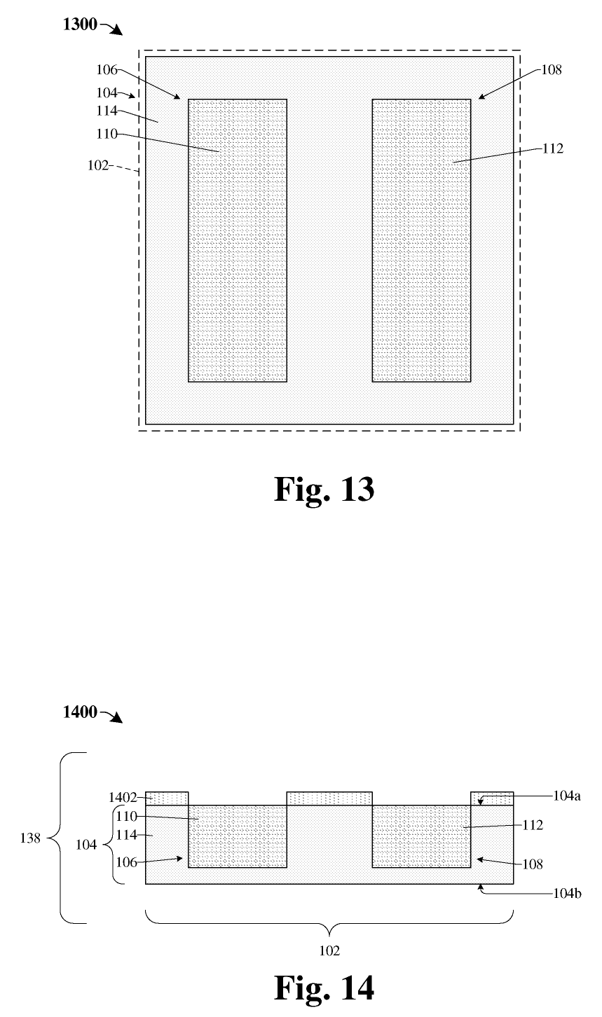

As shown in top view 1300 of FIG. 13 and corresponding cross-sectional view 1400 of FIG. 14, a first photodetector 106 and a second photodetector 108 are formed in a first semiconductor substrate 104. For example, a first photodiode region 110 and a second photodiode region 112 are formed in the first substrate 104 along a frontside 104a of the first substrate 104. A bulk region 114 of the first substrate 104 surrounds the photodiode regions 110, 112. The bulk region 114 of the first substrate 104 has a first doping type (e.g., p-type) and the photodiode regions 110, 112 have a second doping type (e.g., n-type), different than the first doping type. The photodiode regions 110, 112 and the bulk region 114 of the first substrate 104 form the photodetectors 106, 108.

In some embodiments, the photodiode regions 110, 112 are formed in the first substrate 104 by an ion implantation process, a diffusion process, or some other suitable process. In some embodiments, a masking layer 1402 is formed over the frontside 104a of the first substrate 104 and the photodiode regions 110, 112 are formed in the first substrate 104 according to openings in the masking layer 1402. In some embodiments, the masking layer 1402 may, for example, comprise photoresist, a dielectric hard mask, or some other suitable material. The masking layer 1402 is not shown in top view 1300 of FIG. 13.

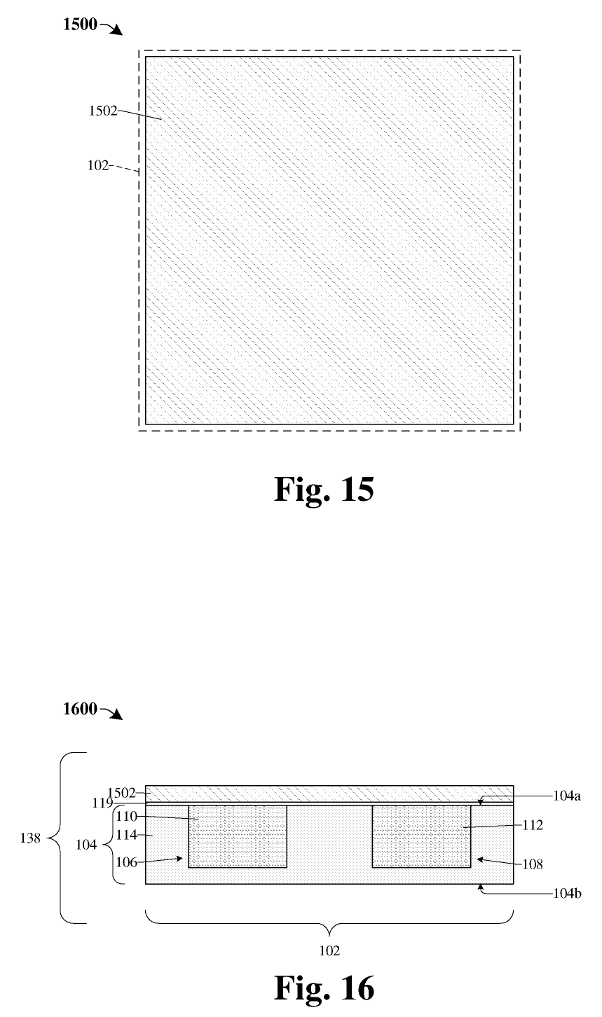

As shown in top view 1500 of FIG. 15 and corresponding cross-sectional view 1600 of FIG. 16, a gate dielectric layer 119 is deposited over the frontside 104a of the first substrate 104 and a gate layer 1502 is deposited over the gate dielectric layer 119. In some embodiments, the gate dielectric layer 119 may, for example, comprise silicon, some high-k dielectric, or some other suitable material. In some embodiments, the gate layer 1502 may, for example, comprise polysilicon, metal, or some other suitable material. In some embodiments, the gate dielectric layer 119 and/or the gate layer 1502 may be deposited by a chemical vapor deposition (CVD) process, a physical vapor deposition (PVD) process, an atomic layer deposition (ALD) process, or some other suitable process.

As shown in top view 1700 of FIG. 17 and corresponding cross-sectional view 1800 of FIG. 18, the gate layer (e.g., 1502 of FIGS. 15 and 16) and the gate dielectric layer 119 are patterned to form a first transfer gate 118 and a second transfer gate 120 from the gate layer 1502. In some embodiments, the patterning comprises forming a masking layer 1802 over the gate layer 1502 and etching the gate layer 1502 and the gate dielectric layer 119 according to the masking layer 1802.

In some embodiments, the etching comprises a dry etching process (e.g., plasma etching, reactive ion etching, ion beam etching, or the like) or some other suitable etching process. In some embodiments, the masking layer 1802 may, for example, comprise photoresist, a dielectric hard mask, or some other suitable material. The masking layer 1802 is not shown in top view 1700 of FIG. 17.

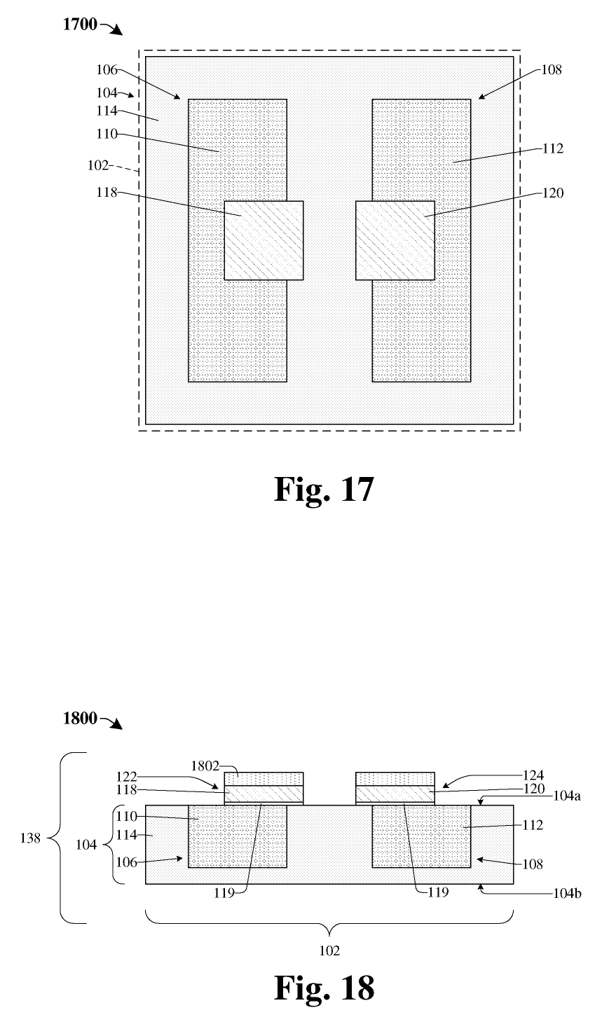

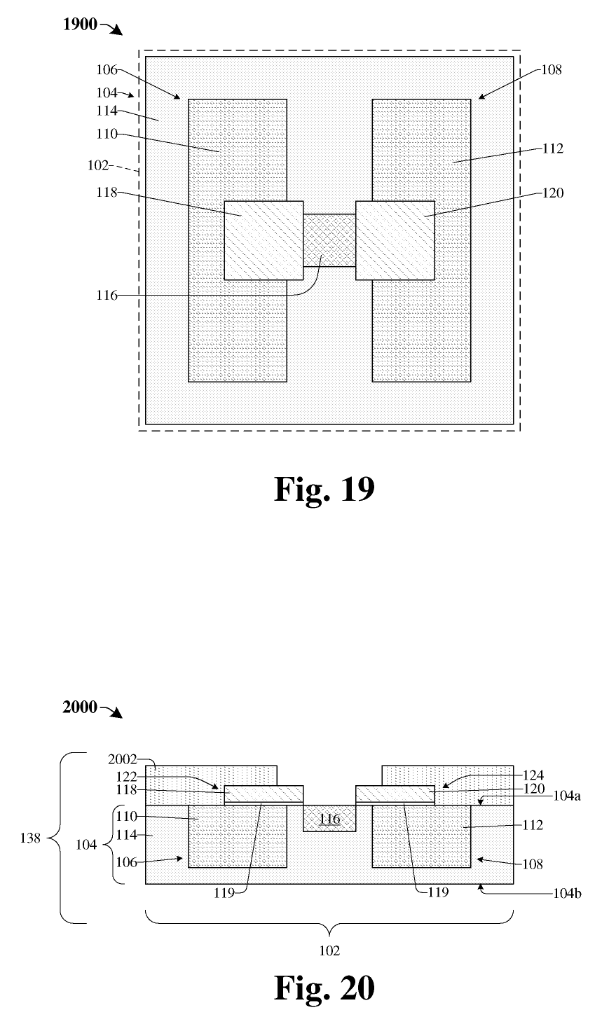

As shown in top view 1900 of FIG. 19 and corresponding cross-sectional view 2000 of FIG. 20, a floating diffusion region 116 is formed in the first substrate 104 along a frontside 104a of the first substrate 104 and between the transfer gates 118, 120. The floating diffusion region 116 has the second doping type (e.g., n-type). By forming the floating diffusion region 116 in the first substrate 104 between the transfer gates 118, 120, a first transfer transistor 122 and a second transfer transistor 124 (which share the floating diffusion region 116) are formed along the first substrate 104.

In some embodiments, the floating diffusion region 116 is formed in the first substrate 104 by an ion implantation process, a diffusion process, or some other suitable process. In some embodiments, a masking layer 2002 is formed over the first substrate 104 and over portions of the transfer gates 118, 120. The floating diffusion region 116 is formed in the first substrate 104 according to an opening in the masking layer 2002 and according to sidewalls of the transfer gates 118, 120. In some embodiments, the masking layer 2002 does not cover portions the transfer gates 118, 120 so the floating diffusion region 116 can be “self-aligned” to the transfer gates 118, 120. In some embodiments, the masking layer 2002 may, for example, comprise photoresist, a dielectric hard mask, or some other suitable material. The masking layer 2002 is not shown in top view 1900 of FIG. 19.

As shown in cross-sectional view 2100 of FIG. 21, a first dielectric structure 130 and a first metal interconnect structure 132 are formed over the transfer transistors 122, 124. In some embodiments, the first dielectric structure 130 is formed by depositing a plurality of dielectric layers over the first substrate 104. In some embodiments, the first metal interconnect structure 132 is formed by forming a plurality of metal contacts 156, metal lines 158, metal vias 160, and metal pads 162 within the first dielectric structure 130. In some embodiments, a top dielectric layer of the first dielectric structure 130 and the metal pads 162 of the first metal interconnect structure 132 form a first bonding layer 2102.

In some embodiments, the dielectric layers of the first dielectric structure 130 comprise silicon dioxide, silicon nitride, or some other suitable material. In some embodiments, the dielectric layers of the first dielectric structure 130 may be deposited by CVD processes, PVD processes, ALD processes, or some other suitable processes. In some embodiments, the metal interconnects of the first metal interconnect structure 132 may comprise copper, aluminum, tungsten, or some other suitable material. In some embodiments, the metal interconnects of the first metal interconnect structure 132 may be formed by etching the dielectric layers of the first dielectric structure 130 and depositing metal over the etched dielectric layers.

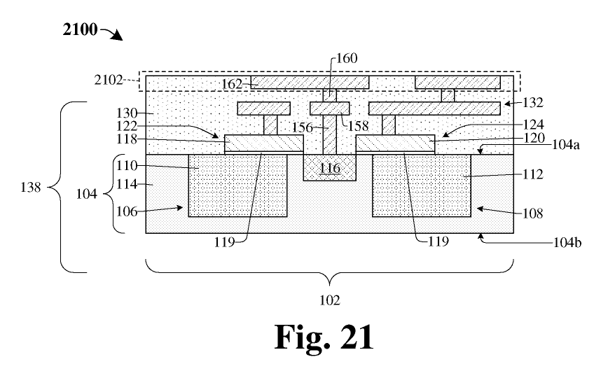

FIG. 22 illustrates top view 2200 and FIG. 23 illustrates corresponding cross-sectional views 2300 of some embodiments of a first method for forming a trench 2302 in the first substrate 104.

As shown in top view 2200 of FIG. 22 and corresponding cross-sectional view 2300 of FIG. 23, a backside 104b of the first substrate 104, opposite the frontside 104a, is etched to form a trench 2302 in the first substrate 104. The trench 2302 is delimited by sidewalls 104c, 104d, 104e, 104f, 104h, 104i of the first substrate 104, a bottom surface 130a of the first dielectric structure 130, and a lower surface 104g of the first substrate 104. The trench 2302 surrounds, and extends between, the first and second photodetectors 106, 108. In some embodiments, the trench 2302 extends through the first substrate 104 to the first dielectric structure 130 except directly over the floating diffusion region 116. Directly over the floating diffusion region 116, the trench 2302 extends to a depth 2306 below the backside 104b of the first substrate 104 that is less than the thickness 2308 of the first substrate 104. Thus, the trench 2302 does not extend through the floating diffusion region 116.

In some embodiments, a masking layer 2304 is formed over the backside 104b of the first substrate 104 and the etching is performed according to the masking layer 2304. In some embodiments, the etching comprises a dry etching process (e.g., plasma etching, reactive ion etching, ion beam etching, or the like) or some other suitable etching process. In some embodiments, the masking layer 2304 may, for example, comprise photoresist, a dielectric hard mask, or some other suitable material. The masking layer 2304 is not shown in top view 2200 of FIG. 22.

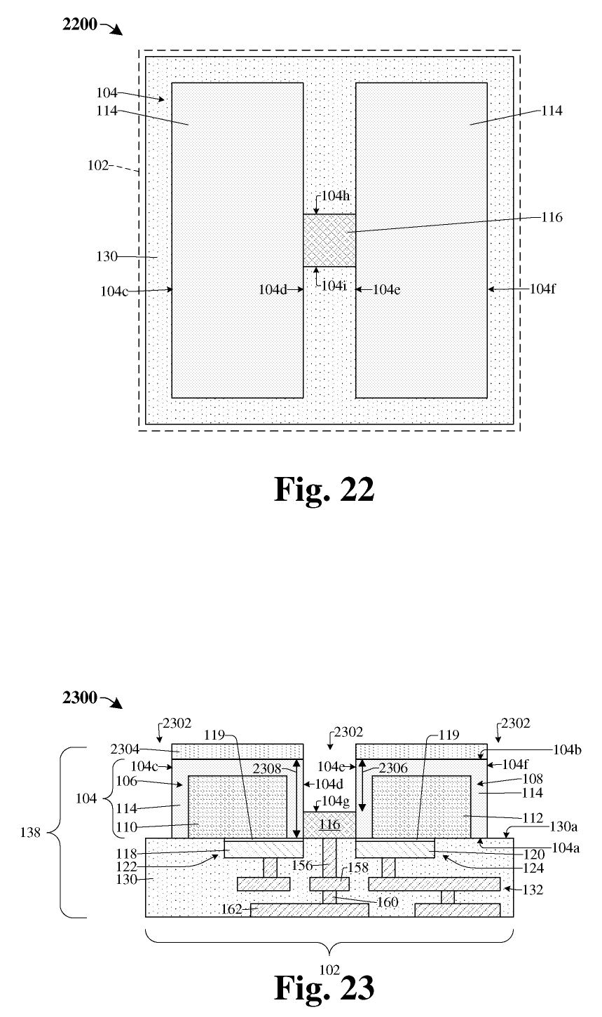

FIGS. 24-27 illustrate views 2400-2700 of some embodiments of a second method for forming a trench 2502 in the first substrate 104.

As shown in top view 2400 of FIG. 24 and corresponding cross-sectional view 2500 of FIG. 25, the backside 104b of the first substrate 104 is etched to form the trench 2502 in the first substrate 104. The trench 2502 is delimited by sidewalls 104c, 104f, 104j, 104k of the first substrate 104 and a bottom surface 130a of the first dielectric structure 130. The trench 2502 does not extend into the first substrate 104 directly over the floating diffusion region 116.

In some embodiments, a masking layer 2504 is formed over the backside 104b of the first substrate 104 and the etching is performed according to the masking layer 2504. The masking layer 2504 is not shown in top view 2400 of FIG. 24.

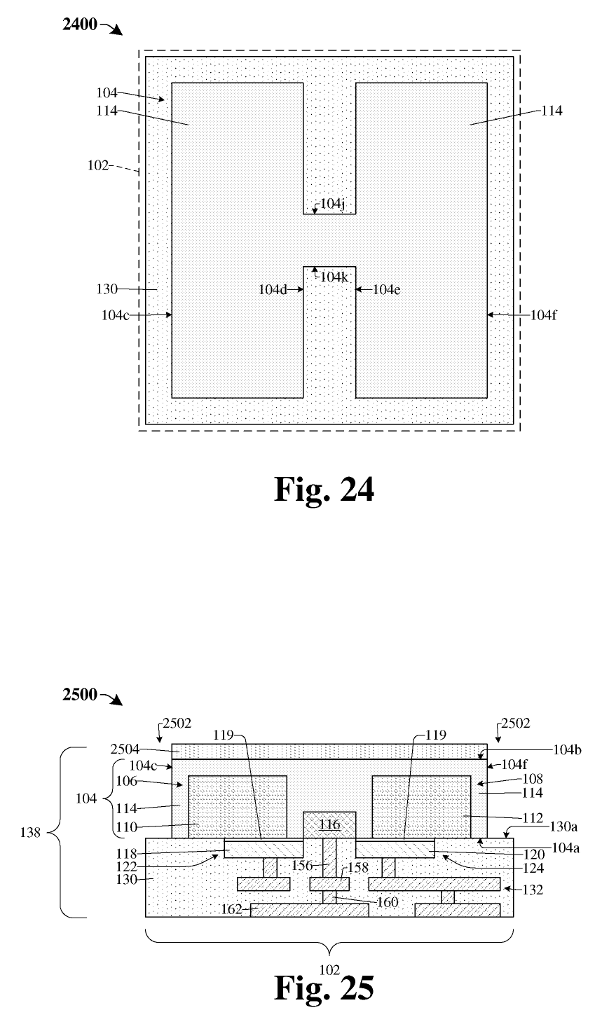

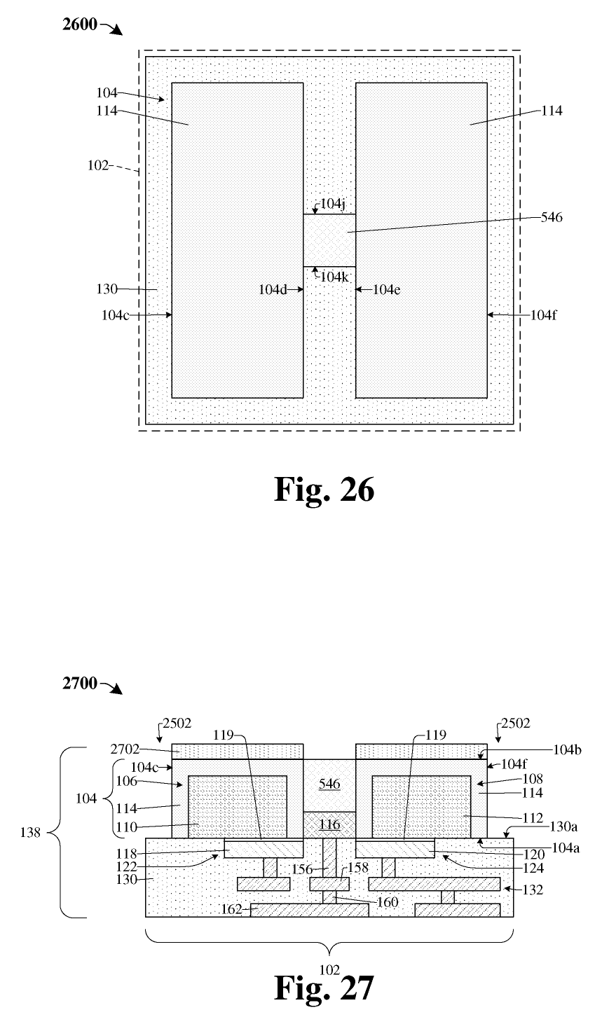

As shown in top view 2600 of FIG. 26 and corresponding cross-sectional view 2700 of FIG. 27, an implant region 546 is formed in the first substrate 104 along the backside 104b of the first substrate 104 and between the photodetectors 106, 108. The implant region 546 has the first doping type (e.g., p-type). In some embodiments, the implant region 546 is formed in the first substrate 104 by an ion implantation process, a diffusion process, or some other suitable process. In some embodiments, a masking layer 2702 is formed over the first substrate 104 and the implant region 546 is formed in the first substrate 104 according to an opening in the masking layer 2702.

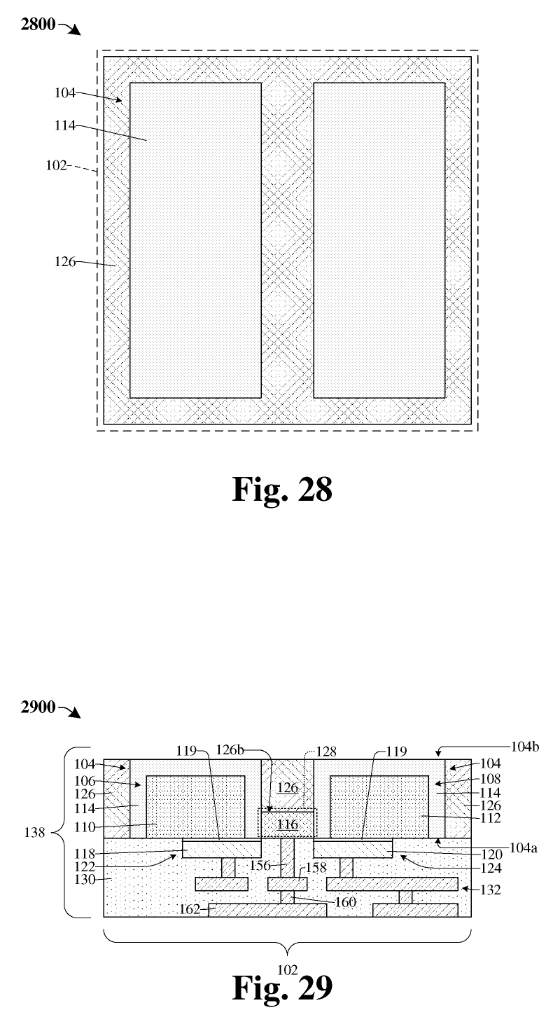

As shown in top view 2800 of FIG. 28 and cross-sectional view 2900 of FIG. 29, a trench isolation layer 126 is formed in the trench (e.g., 2302 of FIG. 23 or 2502 of FIG. 27). In some embodiments, forming the trench isolation layer 126 in the trench includes depositing the trench isolation layer 126 over the backside 104b of the first substrate 104 and in the trench, and performing a planarization process (e.g., a chemical mechanical planarization (CMP) or some other suitable process) on the trench isolation layer 126. In some embodiments, the planarization process removes the trench isolation layer 126 from the backside 104b of the first substrate 104. In some other embodiments (not shown), a portion of the trench isolation layer 126 remains on the backside 104b of the first substrate 104.

In some embodiments, the trench isolation layer 126 comprises silicon dioxide, tungsten, or some other suitable material. In some embodiments, the trench isolation layer 126 may be deposited a CVD process, a PVD process, an ALD process, or some other suitable process.

As shown in cross-sectional view 3000 of FIG. 30, a color filter 134 and a micro-lens 136 are formed over the backside 104b of the first substrate 104.

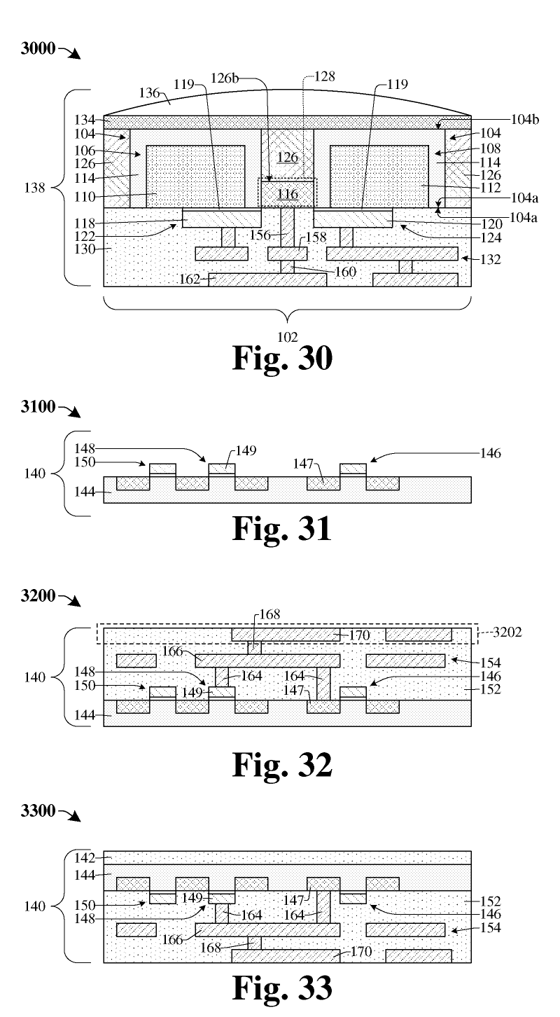

FIGS. 31-34 illustrate views 3100-3400 of some embodiments of a method for forming a second chip 140.

As shown in cross-sectional view 3100 of FIG. 31, a plurality of pixel transistors are formed along a second semiconductor substrate 144. For example, a first pixel transistor 146, a second pixel transistor 148, and a third pixel transistor 150 are formed along a frontside of the second substrate 144.

As shown in cross-sectional view 3200 of FIG. 32, a second dielectric structure 152 and a second metal interconnect structure 154 are formed over the pixel transistors 146, 148, 150. In some embodiments, forming the second dielectric structure 152 includes depositing a plurality of dielectric layers over the second substrate 144. In some embodiments, forming the second interconnect structure 154 includes forming a plurality of metal contacts 164, metal lines 166, metal vias 168, and metal pads 170 within the second dielectric structure 152. In some embodiments, a top dielectric layer of the second dielectric structure 152 and the metal pads 170 of the second interconnect structure 154 form a second bonding layer 3202.

In some embodiments, the dielectric layers of the second dielectric structure 152 may comprise silicon dioxide, silicon nitride, or some other suitable material. In some embodiments, the dielectric layers of the second dielectric structure 152 may be deposited by CVD processes, PVD processes, ALD processes, or some other suitable processes. In some embodiments, the metal interconnects of the second metal interconnect structure 154 may comprise copper, aluminum, tungsten, or some other suitable material.

As shown in cross-sectional view 3300 of FIG. 33, a first backside dielectric layer 142 is formed along a backside of the second substrate 144. In some embodiments, the first backside dielectric layer 142 may comprise silicon dioxide, silicon nitride, or some other suitable material. In some embodiments, the first backside dielectric layer 142 may be deposited by CVD processes, PVD processes, ALD processes, or some other suitable processes.

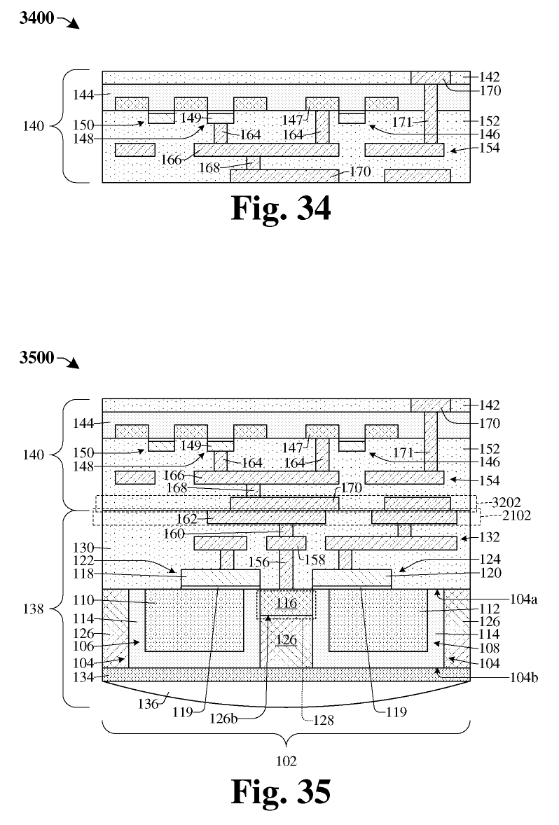

As shown in cross-sectional view 3400 of FIG. 34, a TSV 171 is formed in the second chip 140. In some embodiments, the TSV 171 is formed by etching the first backside dielectric layer 142, the second substrate 144, and the second dielectric structure 152, depositing metal over the etched layers, and planarizing the metal.

As shown in cross-sectional view 3500 of FIG. 35, the first chip 138 and the second chip 140 are bonded together along the first dielectric structure 130, the second dielectric structure 152, the first metal interconnect structure 132, and the second metal interconnect structure 154. For example, the first chip 138 and the second chip 140 are bonded together along the first and second bonding layers 2102, 3202. The bonding couples the metal interconnect structures 132, 154 so that the floating diffusion region 116 of the first chip 138 is coupled to the pixel transistors 146, 148, 150 of the second chip 140 by the first and second metal interconnect structures 132, 154. In some embodiments, the bonding comprises a fusion bonding process or some other suitable process.

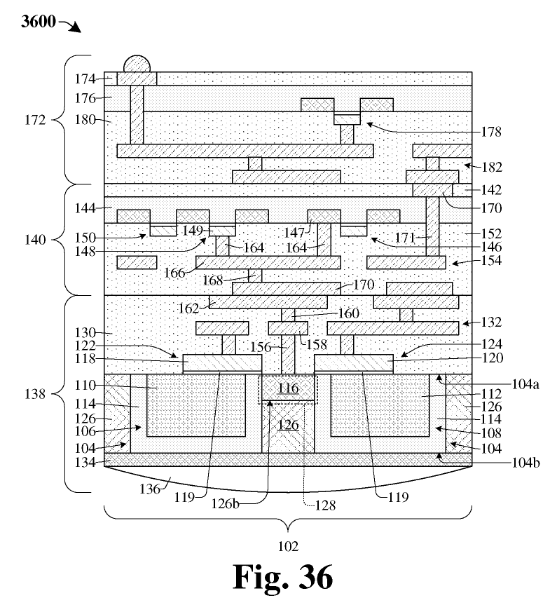

As shown in cross-sectional view 3600 of FIG. 36, a third chip 172 is bonded over the backside of the second chip 140. The third chip 172 comprises a third semiconductor substrate 176, a transistor 178 along the third substrate 176, a third dielectric structure 180 along a frontside of the third substrate 176, a third metal interconnect structure 182 in the third dielectric structure 180, and a second backside dielectric layer 174 along a backside of the third substrate 176. In some embodiments, the third chip 172 is bonded to the second chip 140 along the first backside dielectric layer 142 and the third dielectric structure 180 of the third chip 172. In some embodiments, the bonding comprises a fusion bonding process or some other suitable process.

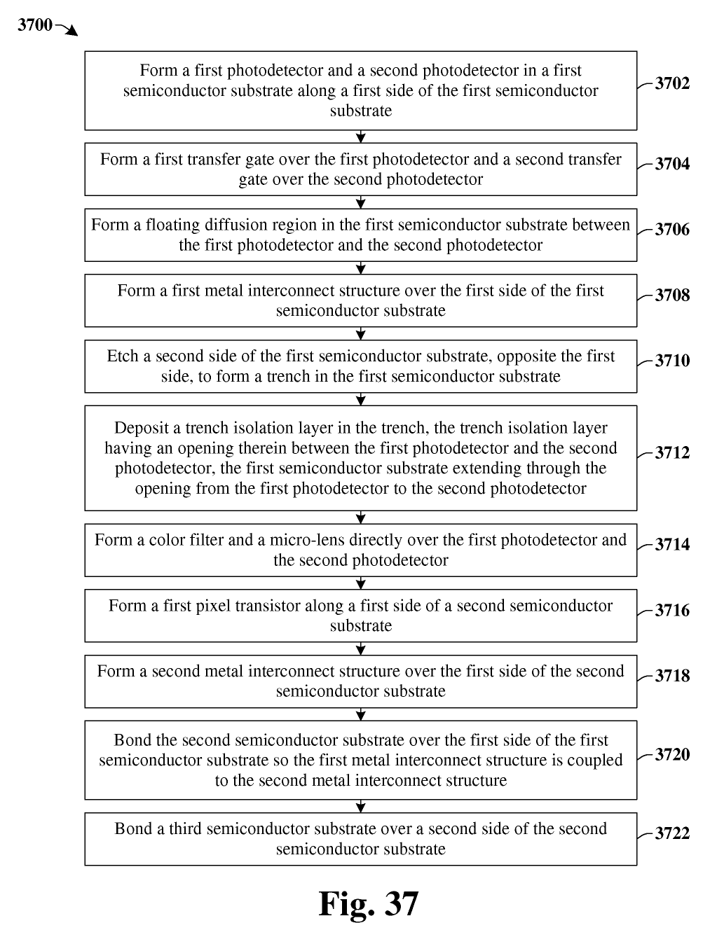

FIG. 37 illustrates a flow diagram of some embodiments of a method 3700 for forming an integrated chip comprising a pixel along a first semiconductor substrate. While method 3700 is illustrated and described below as a series of acts or events, it will be appreciated that the illustrated ordering of such acts or events are not to be interpreted in a limiting sense. For example, some acts may occur in different orders and/or concurrently with other acts or events apart from those illustrated and/or described herein. In addition, not all illustrated acts may be required to implement one or more aspects or embodiments of the description herein. Further, one or more of the acts depicted herein may be carried out in one or more separate acts and/or phases.

At block 3702, form a first photodetector and a second photodetector in a first semiconductor substrate along a first side of the first semiconductor substrate. FIG. 13 illustrates a top view 1300 and FIG. 14 illustrates a corresponding cross-sectional view 1400 of some embodiments corresponding to block 3702.

At block 3704, form a first transfer gate over the first photodetector and a second transfer gate over the second photodetector. FIG. 17 illustrates a top view 1700 and FIG. 18 illustrates a corresponding cross-sectional view 1800 of some embodiments corresponding to block 3704.

At block 3706, form a floating diffusion region in the first semiconductor substrate between the first photodetector and the second photodetector. FIG. 19 illustrates a top view 1900 and FIG. 20 illustrates a corresponding cross-sectional view 2000 of some embodiments corresponding to block 3706.

At block 3708, form a first metal interconnect structure over the first side of the first semiconductor substrate. FIG. 21 illustrates a cross-sectional view 2100 of some embodiments corresponding to block 3708.

At block 3710, etch a second side of the first semiconductor substrate, opposite the first side, to form a trench in the first semiconductor substrate. FIGS. 22 and 24 illustrate top views 2200, 2400 of some embodiments corresponding to block 3710. FIGS. 23 and 25 illustrate corresponding cross-sectional views 2300, 2500 of some embodiments corresponding to block 3710.

At block 3712, deposit a trench isolation layer in the trench, the trench isolation layer having an opening therein between the first photodetector and the second photodetector, the first semiconductor substrate extending through the opening from the first photodetector to the second photodetector. FIG. 28 illustrates a top view 2800 and FIG. 29 illustrates a corresponding cross-sectional view 2900 of some embodiments corresponding to block 3712.

At block 3714, form a color filter and a micro-lens directly over the first photodetector and the second photodetector. FIG. 30 illustrates a cross-sectional view 3000 of some embodiments corresponding to block 3714.

At block 3716, form a first pixel transistor along a first side of a second semiconductor substrate. FIG. 31 illustrates a cross-sectional view 3100 of some embodiments corresponding to block 3716.

At block 3718, form a second metal interconnect structure over the first side of the second semiconductor substrate. FIG. 32 illustrates a cross-sectional view 3200 of some embodiments corresponding to block 3718.

At block 3720, bond the second semiconductor substrate over the first side of the first semiconductor substrate so the first metal interconnect structure is coupled to the second metal interconnect structure. FIG. 35 illustrates a cross-sectional view 3500 of some embodiments corresponding to block 3720.

At block 3722, bond a third semiconductor substrate over a second side of the second semiconductor substrate. FIG. 36 illustrates a cross-sectional view 3600 of some embodiments corresponding to block 3722.

Thus, the present disclosure relates to an integrated chip and a method for forming the integrated chip, the integrated chip including a dual photodetector pixel along a first substrate and pixel transistors along a second substrate that is spaced over the first substrate.

Accordingly, in some embodiments, the present disclosure relates to an integrated chip including a first semiconductor substrate. The first semiconductor substrate includes a doped region. A first photodetector and a second photodetector are in the first semiconductor substrate. The second photodetector is laterally spaced from the first photodetector. A trench isolation layer at least partially surrounds the first photodetector and the second photodetector and extends between the first photodetector and the second photodetector. The trench isolation layer has a first pair of sidewalls between the first photodetector and the second photodetector. The first semiconductor substrate extends from the first photodetector, between the first pair of sidewalls of the trench isolation layer, to the second photodetector. The doped region is between the first pair of sidewalls of the trench isolation layer. A first gate and a second gate are over the first photodetector and the second photodetector, respectively. The first photodetector and the first gate partially form a first transistor. The second photodetector and the second gate partially form a second transistor. A first metal interconnect and a second metal interconnect are over the first gate and the second gate, respectively. The first metal interconnect is coupled to the first gate. The second metal interconnect is coupled to the second gate. A second semiconductor substrate is over and spaced from the first gate and the second gate. A third transistor is along the second semiconductor substrate. The third transistor is coupled to the first transistor.

In other embodiments, the present disclosure relates to an integrated chip including a first semiconductor substrate, the first semiconductor substrate including a shared floating diffusion region. A first photodetector and a second photodetector are in the first semiconductor substrate. The first photodetector and the second photodetector are on opposite sides of the shared floating diffusion region. A first transfer gate and a second transfer gate are over the first photodetector and the second photodetector, respectively. The first photodetector, the shared floating diffusion region, and the first transfer gate partially form a first transfer transistor. The second photodetector, the shared floating diffusion region, and the second transfer gate partially form a second transfer transistor. A first metal interconnect and a second metal interconnect are over the first transfer gate and the second transfer gate, respectively. The first metal interconnect is coupled to the first transfer gate. The second metal interconnect is coupled to the second transfer gate. A second semiconductor substrate is over and spaced from the first transfer transistor and the second transfer transistor. A first pixel transistor is along the second semiconductor substrate. A third metal interconnect is between the first pixel transistor and the shared floating diffusion region. The third metal interconnect is coupled to the first pixel transistor and the shared floating diffusion region. A trench isolation layer laterally surrounds the first photodetector and the second photodetector. The trench isolation layer extending between the first photodetector and the second photodetector. A first pair of sidewalls of the trench isolation layer delimit an opening in the trench isolation layer and between the first photodetector and the second photodetector. The first semiconductor substrate extends from the first photodetector, between the first pair of sidewalls of the trench isolation layer, to the second photodetector. The shared floating diffusion region is between the first pair of sidewalls of the trench isolation layer.

In yet other embodiments, the present disclosure relates to a method for forming an integrated chip. The method includes forming a first photodetector and a second photodetector in a first semiconductor substrate along a first side of the first semiconductor substrate. A first transfer gate and a second transfer gate are formed over the first photodetector and the second photodetector, respectively. A floating diffusion region is formed in the first semiconductor substrate between the first photodetector and the second photodetector. A first metal interconnect is formed over and coupled to the first transfer gate. A second metal interconnect is formed over and coupled to the second transfer gate. A third metal interconnect is formed over and coupled to the floating diffusion region. A trench isolation layer is formed surrounding the first photodetector and the second photodetector and extending between the first photodetector and the second photodetector. The trench isolation layer has an opening therein between the first photodetector and the second photodetector. The first semiconductor substrate extends through the opening from the first photodetector to the second photodetector. A first pixel transistor is formed along a first side of a second semiconductor substrate. A fourth metal interconnect is formed over and coupled to the first pixel transistor. The second semiconductor substrate is bonded over the first side of the first semiconductor substrate so the third metal interconnect is coupled to the fourth metal interconnect.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated chip comprising:
a first semiconductor substrate comprising a doped region;
a first photodetector and a second photodetector in the first semiconductor substrate, the second photodetector laterally spaced from the first photodetector;
a trench isolation layer at least partially surrounding the first photodetector and the second photodetector and extending between the first photodetector and the second photodetector, the trench isolation layer having a first pair of sidewalls between the first photodetector and the second photodetector, wherein the first semiconductor substrate extends from the first photodetector, between the first pair of sidewalls of the trench isolation layer, to the second photodetector, and wherein the doped region is between the first pair of sidewalls of the trench isolation layer;
a first gate and a second gate over the first photodetector and the second photodetector, respectively, the first photodetector and the first gate partially forming a first transistor, the second photodetector and the second gate partially forming a second transistor;
a first metal interconnect and a second metal interconnect over the first gate and the second gate, respectively, the first metal interconnect coupled to the first gate, the second metal interconnect coupled to the second gate;
a second semiconductor substrate over and spaced from the first gate and the second gate; and
a third transistor along the second semiconductor substrate, wherein the third transistor is coupled to the first transistor.

2. The integrated chip of claim 1, the first semiconductor substrate further comprising a bulk region having a first doping type, a first photodiode region having a second doping type, different than the first doping type, and a first floating diffusion region having the second doping type, wherein the bulk region and the first photodiode region form the first photodetector, wherein the first floating diffusion region further forms the first transistor, and wherein the doped region has the first doping type.

3. The integrated chip of claim 1, wherein the first metal interconnect is isolated from the second metal interconnect and the second gate.

4. The integrated chip of claim 1, further comprising:
a color filter and a micro-lens under both the first photodetector and the second photodetector.

5. The integrated chip of claim 1, the first semiconductor substrate further comprising a bulk region having a first doping type and a first photodiode region having a second doping type, different than the first doping type, wherein the bulk region and the first photodiode region form the first photodetector, wherein the doped region is a floating diffusion region having the second doping type, wherein the floating diffusion region further forms the first transistor and the second transistor, and wherein the third transistor is coupled to the floating diffusion region.

6. The integrated chip of claim 5, further comprising:
a first metal contact contacting the floating diffusion region; and
a second metal contact contacting a gate of the third transistor, wherein the second metal contact and the first metal contact couple the gate of the third transistor to the floating diffusion region.

7. The integrated chip of claim 6, further comprising:
a fourth transistor along the second semiconductor substrate; and
a third metal contact contacting a source/drain region of the fourth transistor, wherein the third metal contact and the first metal contact couple the source/drain region of the fourth transistor to the floating diffusion region.

8. The integrated chip of claim 5, further comprising:
a third photodetector and a fourth photodetector in the first semiconductor substrate; and
a third gate and a fourth gate over the third photodetector and the third photodetector, respectively,
wherein the trench isolation layer laterally surrounds the third photodetector and the fourth photodetector, wherein the trench isolation layer extends between the third photodetector and the fourth photodetector, between the third photodetector and the first photodetector, and between the fourth photodetector and the second photodetector, wherein the first pair of sidewalls of the trench isolation layer is between the first photodetector, the second photodetector, the third photodetector, and the fourth photodetector, wherein the first semiconductor substrate extends from the first photodetector, between the first pair of sidewalls of the trench isolation layer, to the second photodetector, the third photodetector, and the fourth photodetector.

9. The integrated chip of claim 8, wherein the third photodetector, the floating diffusion region, and the third gate partially form a fourth transistor, and wherein the fourth photodetector, the floating diffusion region, and the fourth gate partially form a fifth transistor.

10. The integrated chip of claim 9, wherein the trench isolation layer has a second pair of sidewalls between the first photodetector and the second photodetector, the second pair of sidewalls spaced from the first pair of sidewalls, wherein the first semiconductor substrate extends from the first photodetector, between the second pair of sidewalls, to the second photodetector, wherein the first semiconductor substrate further comprises an implant region between the second pair of sidewalls, the implant region having the first doping type.

11. The integrated chip of claim 1, further comprising:
a third semiconductor substrate over and spaced from the second semiconductor substrate; and
a fourth transistor arranged along the third semiconductor substrate and coupled to the third transistor.

12. An integrated chip comprising:
a first semiconductor substrate comprising a shared floating diffusion region;
a first photodetector and a second photodetector in the first semiconductor substrate, the first photodetector and the second photodetector on opposite sides of the shared floating diffusion region;
a first transfer gate and a second transfer gate over the first photodetector and the second photodetector, respectively, the first photodetector, the shared floating diffusion region, and the first transfer gate partially forming a first transfer transistor, the second photodetector, the shared floating diffusion region, and the second transfer gate partially forming a second transfer transistor;
a first metal interconnect and a second metal interconnect over the first transfer gate and the second transfer gate, respectively, the first metal interconnect coupled to the first transfer gate, the second metal interconnect coupled to the second transfer gate;
a second semiconductor substrate over and spaced from the first transfer transistor and the second transfer transistor;
a first pixel transistor along the second semiconductor substrate;
a third metal interconnect between the first pixel transistor and the shared floating diffusion region, the third metal interconnect coupled to the first pixel transistor and the shared floating diffusion region; and
a trench isolation layer laterally surrounding the first photodetector and the second photodetector, the trench isolation layer extending between the first photodetector and the second photodetector, wherein a first pair of sidewalls of the trench isolation layer delimit an opening in the trench isolation layer and between the first photodetector and the second photodetector,
wherein the first semiconductor substrate extends from the first photodetector, between the first pair of sidewalls of the trench isolation layer, to the second photodetector, and wherein the shared floating diffusion region is between the first pair of sidewalls of the trench isolation layer.

13. The integrated chip of claim 12, wherein the opening is further delimited by an upper surface of the trench isolation layer.

14. The integrated chip of claim 12, wherein the first semiconductor substrate further comprising a bulk region having a first doping type and a first photodiode region having a second doping type, different than the first doping type, wherein the bulk region and the first photodiode region form the first photodetector, wherein the shared floating diffusion region has the second doping type,
wherein the first semiconductor substrate further comprises an implant region having the first doping type, and wherein the implant region is between the first pair of sidewalls of the trench isolation layer and under the shared floating diffusion region.

15. The integrated chip of claim 12, further comprising:
a third photodetector and a fourth photodetector in the first semiconductor substrate; and
a third transfer gate and a fourth transfer gate over the third photodetector and the third photodetector, respectively,
wherein the trench isolation layer laterally surrounds the third photodetector and the fourth photodetector, wherein the trench isolation layer extends between the third photodetector and the fourth photodetector, between the third photodetector and the first photodetector, and between the fourth photodetector and the second photodetector, wherein a second pair of sidewalls of the trench isolation layer further delimit the opening in the trench isolation layer, wherein the first semiconductor substrate extends continuously from the first photodetector, between the first pair of sidewalls and the second pair of sidewalls of the trench isolation layer, to the second photodetector, the third photodetector, and the fourth photodetector, and wherein the shared floating diffusion region is disposed between the second pair of sidewalls of the trench isolation layer,
wherein the third photodetector, the shared floating diffusion region, and the third transfer gate partially form a third transfer transistor, and wherein the fourth photodetector, the shared floating diffusion region, and the fourth transfer gate partially form a fourth transfer transistor.

16. The integrated chip of claim 12, further comprising:
a color filter and a micro-lens directly under the first photodetector and the second photodetector.

17. A method for forming an integrated chip, the method comprising:
forming a first photodetector and a second photodetector in a first semiconductor substrate along a first side of the first semiconductor substrate;
forming a first transfer gate and a second transfer gate over the first photodetector and the second photodetector, respectively;
forming a floating diffusion region in the first semiconductor substrate between the first photodetector and the second photodetector;
forming a first metal interconnect over and coupled to the first transfer gate, a second metal interconnect over and coupled to the second transfer gate, and a third metal interconnect over and coupled to the floating diffusion region;
forming a trench isolation layer surrounding the first photodetector and the second photodetector and extending between the first photodetector and the second photodetector, the trench isolation layer having an opening therein between the first photodetector and the second photodetector, the first semiconductor substrate extending through the opening from the first photodetector to the second photodetector;
forming a first pixel transistor along a first side of a second semiconductor substrate;
forming a fourth metal interconnect over and coupled to the first pixel transistor; and
bonding the second semiconductor substrate over the first side of the first semiconductor substrate so the third metal interconnect is coupled to the fourth metal interconnect.

18. The method of claim 17, wherein the floating diffusion region is in the opening in the trench isolation layer.

19. The method of claim 17, wherein forming the trench isolation layer comprises etching a second side of the first semiconductor substrate, opposite the first side, to form a trench in the first semiconductor substrate, and depositing the trench isolation layer in the trench.

20. The method of claim 17, further comprising:
forming a color filter and a micro-lens directly over the first photodetector and the second photodetector; and
bonding a third semiconductor substrate over a second side of the second semiconductor substrate, opposite the first side of the second semiconductor substrate.
